(19) United States
(12) Patent Application Publication
(10) Pub. No.: US 2015/0325759 A1
(43) Pub. Date: Nov. 12, 2015

(54) OPTICAL ELEMENT WITH INTEGRATED INDICATOR

(71) Applicant: CREE, INC., Durham, NC (US)

(72) Inventors: Kurt Wilcox, Libertyville, IL (US); Theodore Lowes, Lompoc, CA (US); Corey Goldstein, Kenosha, WI (US); Jason Taylor, Cary, NC (US); Chandan Bhat, Goleta, CA (US)

(73) Assignee: CREE, INC., Durham, NC (US)

(21) Appl. No.: 14/271,116

(22) Filed: May 6, 2014

(51) Int. Cl. H01L 33/58; F21V 5/04; H01L 33/62; H01L 23/544; H01L 33/56; H01L 33/48

(52) U.S. Cl. CPC H01L 33/58; H01L 33/56; H01L 33/483; H01L 33/486; H01L 33/62; H01L 23/544; F21V 5/04; H01L 2933/0058; H01L 2933/0033; H01L 2223/54433

(57) ABSTRACT

Solid state fixtures and packages are disclosed that include an optical element, such as an encapsulant, having an integrated indicator which indicates one or more characteristics of the package to a user, such as package orientation, polarity, chip-type, etc. The host optical element can be substantially symmetrical but for the indicator. Indicators can be additive, such as a bump, or subtractive, such as a hole. The indicator can be visible to the human eye, and/or can be machine detectable, such as by pick-and-place technology. Indicators can be formed by many processes including molding and laser ablation/imprinting, which is particularly suited for use with a hard host material.

### BACKGROUND OF THE INVENTION

1. Field of the Invention

This invention pertains generally to light emitters and the optical elements used therewith, and particularly to optical elements having an integrated indicator.

2. Description of the Related Art

Incandescent or filament-based lamps or bulbs are commonly used as light sources for both residential and commercial facilities. However, such lamps are highly inefficient light sources, with as much as 95% of the input energy lost, primarily in the form of heat or infrared energy. One common alternative to incandescent lamps, so-called compact fluorescent lamps (CFLs), are more effective at converting electricity into light but require the use of toxic materials which, along with its various compounds, can cause both chronic and acute poisoning and can lead to environmental pollution. One solution for improving the efficiency of lamps or bulbs is to use solid state devices such as light emitting diodes (LED or LEDs), rather than metal filaments, to produce light.

Light emitting diodes generally comprise one or more active layers of semiconductor material sandwiched between oppositely doped layers. When a bias is applied across the doped layers, holes and electrons are injected into the active layer where they recombine to generate light. Light is emitted from the active layer and from various surfaces of the LED.

In order to use an LED chip in a circuit or other like arrangement, it is known to enclose an LED chip in a package to provide environmental and/or mechanical protection, color selection, light focusing and the like. An LED package can also include electrical leads, contacts or traces for electrically connecting the LED package to an external circuit.

In a typical LED package 10 illustrated in FIG. 1, one or more LED chips 14 are mounted onto a carrier 16 such as a printed circuit board (PCB) carrier, substrate, or submount. The LED chips 14 can be attached in many different manners, such as by solder or a conductive epoxy, although other materials are possible. The LED chips can include ohmic contacts for providing an electrical connection. The package 10 can include an encapsulant 12. The encapsulant 12 may contain a wavelength conversion material, such as a phosphor. Light emitted by the LED at a first wavelength may be absorbed by the phosphor, which may responsively emit light at a second wavelength. The package can emit a combination of converted and unconverted light.

Packages and fixtures that emit a combination of different wavelengths of light, and particularly multicolor source packages and fixtures with chips emitting different wavelengths, often cast shadows with color separation and provide an output with poor color uniformity. For example, a package featuring blue and yellow sources may appear to have a blue tint when viewed head on and a yellow tint when viewed from the side. Thus, one challenge associated with multicolor light sources is good spatial color mixing over the entire range of viewing angles to achieve acceptable color spatial uniformity (“CSU”). An LED package with good CSU will emit light of relatively constant CCT across many viewing angles. One known approach to the problem of color mixing is to use a diffuser to scatter light from the various sources. Another known method is to reflect or bounce the light off of several surfaces before it is emitted.

Many different encapsulant shapes are possible. The encapsulant 12 is cylindrical. The encapsulant can be shaped for purposes including but not limited to maximizing efficiency and improving color mixing. For example, many traditional packages utilize a hemispheric encapsulant, which can minimize total internal reflection, to improve output efficiency.

Unlike incandescent lights which illuminate regardless of electrical polarity, LEDs will only light when forward-biased. If reverse-biased, very little current flows and no light is emitted. If a package and/or encapsulant is substantially symmetrical, such as the package 10 and encapsulant 12, LED packages can contain orientation indicators to ensure that they are correctly mounted such that the LED(s) will be forward-biased. Packages such as the package 10 must be mounted on a mount surface such that the LEDs therein will be forward-biased when operating.

Referring to FIG. 1, in traditional packages typically at least a portion of a top surface 16a of the substrate 16 will be uncovered by the encapsulant 12. Some examples of when a large portion of substrate top surface is available include embodiments where an encapsulant is non-rectangular, since substrates are typically rectangular and thus will have some uncovered portion, and when an encapsulant has a smaller footprint than the substrate. Many different embodiments are possible. A polarity indicator 18 can be included on the uncovered portion of the top surface 16a. The polarity indicator 18 can be visible to the human eye such that a technician can correctly mount the package 10 such that the LEDs will be forward-biased. Alternatively, the polarity indicator 18 may not be visible to the human eye but instead be machine-readable. Once a reader indicates that the polarity indicator 18 is in a certain position, a technician will be able to correctly mount the package 10.

Some newer LED packages do not include an uncovered portion of a mount surface. This can help to minimize the overall package footprint. For example, FIGS. 2A and 2B show a package 20 with an encapsulant 22 that covers the entirety of the top surface 26a of the substrate 26. The package 20 can be, for example, about 1 mm² to about 4 mm², or in one specific embodiment about 2.56 mm², although other sizes are possible. Encapsulants covering the entire top surface of a substrate can have distinct advantages, as described in U.S. patent application Ser. No. 13/770,389 to Lowes et al. and entitled “LED Package with Multiple Element Light Source and Encapsulant having Planar Surfaces,” which is commonly assigned with the present application and fully incorporated by reference herein in its entirety. The package 20 includes a top polarity indicator 28a which can in some instances be visible to the human eye, such as if the encapsulant 22 is substantially clear. In this case, the polarity indicator 28a is on an element other than the substrate 26, or in this case on a die attach pad.

However, as described above, many modern packages include encapsulants which include wavelength conversion material such as phosphor. For example, FIG. 3 is a photograph of a package 30 similar to that shown in FIGS. 2A and 2B comprising phosphor in the encapsulant 32. While the encapsulant 32 allows light to exit the package 30 from the emitters mounted therein, in some embodiments no top surface of the substrate is visible or the top surface is difficult to see, and thus no top surface is available for polarity indication. Further, the use of the sides of the substrate 36 is impractical due to, for example, typical package manufacturing processes. Emitter packages are typically manufactured as part of a wafer, and then singulated into individual packages. Markings on the side of a substrate would have to be applied to individual devices after singulation, which would be tedious and cost-inefficient.

One solution to this problem is to include a polarity indicator on the bottom of the package. Referring back to FIG. 2B, the package 20 includes solder pads 24a, 24b which can be used for mounting. The solder pad 24b includes a bottom polarity indicator 28b, in this case a notch. The polarity indicator 28b can be detected with up-looking cameras during manufacturing. However, this process can be more expensive and less reliable than human identification of a polarity indicator. Alternatively, a technician could inspect the bottom of the package 20 to determine the correct mounting position; however, this adds time and labor to the manufacturing process.

The need exists for reliable and cost-effective methods of indicating package polarity in certain types of packages, while at the same time avoiding the sacrifice or alteration of other package characteristics.

### SUMMARY OF THE INVENTION

Briefly, and in general terms, the invention is directed toward polarity indicators in, on, or otherwise included with optical elements.

One embodiment of a light emitting device according to the present invention includes an optical element comprising an indicator.

One embodiment of an optical element according to the present invention is shaped to define an integrated indicator.

One method of forming an optical element according to the present invention can include providing a substantially symmetrical optical element and forming an integrated indicator such that the optical element is no longer substantially symmetrical.

One embodiment of an emitter wafer according to the present invention can include a plurality of emitter packages collectively having one or more common layers. The one or more common layers can include a top layer that is shaped to define an integrated indicator in each of the emitter packages.

These and other aspects and advantages of the invention will become apparent to those skilled in the art from the following detailed description and the accompanying drawings, which illustrate by way of example the features of the invention.

### BRIEF DESCRIPTION OF THE DRAWINGS

FIG. 1 is a perspective view of one embodiment of a prior art emitter package;

FIGS. 2A and 2B are top perspective and bottom perspective views of another embodiment of a prior art emitter package;

FIG. 3 is a top perspective photograph of an emitter package similar to that shown in FIGS. 2A and 2B;

FIGS. 4A-4C are top perspective, top, and side views of one embodiment of an emitter package according to the present invention;

FIGS. 5A and 5B are output profile graphs of a prior art package and one embodiment of an emitter package according to the present invention, respectively;

FIGS. 6A and 6B are color output profiles of a prior art package along two axes and FIGS. 6C and 6D are color output profiles of one embodiment of an emitter package according to the present invention along the same two axes;

FIGS. 7A-7C are top perspective, top, and side views of one embodiment of an emitter package according to the present invention;

FIGS. 7D and 7E are color output profiles of one embodiment of an emitter package according to the present invention along two axes;

FIGS. 8A-8C are top perspective, top, and side views of one embodiment of an emitter package according to the present invention;

FIGS. 9A-9C are top perspective, top, and side views of one embodiment of an emitter package according to the present invention;

FIG. 10 is a top perspective view of one embodiment of an emitter package according to the present invention;

FIGS. 11A and 11B are top perspective and side views of one embodiment of an emitter package according to the present invention;

FIG. 12 is a cross-sectional view of one embodiment of an emitter package according to the present invention;

FIG. 13 is a graph of non-contact surface profilometer readings of a common layer according to the present invention;

FIG. 14 is a top view of an emitter wafer according to the present invention;

FIGS. 15A and 15B are top views of a prior art package and one embodiment of an emitter package according to the present invention;

FIGS. 16A and 16B are further top views of the packages from FIGS. 15A and 15B, respectively;

FIGS. 17A and 17B are further top views of the packages from FIGS. 15A and 15B, respectively;

FIG. 18A is a screenshot of pick-and-place software images of a prior art package and one embodiment of an emitter package according to the present invention;

FIG. 18B is a screenshot of a pick-and-place software image of one embodiment of an emitter package according to the present invention; and

FIG. 18C is a screenshot of a pick-and-place software image of a prior art package.

### DETAILED DESCRIPTION OF THE INVENTION

The present invention is directed toward indicators that can be included in encapsulants or other optical elements. Indicators can make determining the mounting orientation of the device easier for a technician or mounting mechanism while having little or no effect on device output. Indicators can be additive (e.g., a “bump”) or subtractive (e.g., a “hole”), and can be formed in many different ways. Indicators that are defined by the shape of an optical element, or integrated indicators, can be particularly useful when indicators would not be visible on a traditional indication surface, such as the top surface of a substrate.

Integrated indicators can take many different forms and can be included with many different types of optical elements. For example, an additive indicator can take the form of a bump on an optical element, whereas a subtractive indicator can take the form of a dip within the optical element. Indicators can be included with encapsulants and remote phosphor elements of any type or shape, as well as with many other types of optical elements.

Integrated indicators can be large enough to be visible to the human eye while minimizing any effect on the package or fixture output. For example, an indicator can have a diameter of about 200 μm to about 500 μm, or about 300 μm. Packages with encapsulants including integrated polarity indicators have been tested to have the same or about the same lumen output and a similar or negligibly different beam spread as equivalent packages without an indicator.

Integrated indicators can be included in traditional optical materials such as silicone. One method for forming silicone optical elements with an indicator is molding. Laser imprinting or ablation can be used with many different optical materials, including but not limited to glass. In one embodiment the laser can be pulsed while either the laser or a host wafer is moved, such that the laser deposits an indicator at the same spot of each package with each pulse. In another embodiment the laser can be continuously on while either the laser or host wafer is moved, depositing a line or trench indicator that is not along a line of symmetry, such as the x- or y-axis or a diagonal of a rectangle.

Indicators according to the present invention can communicate many different types of information to a technician or mounting mechanism. For instance, in some embodiments the indicator is used to communicate one or more pieces of information about that specific package. For instance, the location of an indicator can communicate the polarity of the package, the orientation in which the package is to be mounted, the location of one or more solder pads, and/or the primary emission direction of the package. “Location” as used herein can also include a direction communicated by an indicator. For example, an indicator can be in the center of an optical element, but can be shaped to indicate one side/corner of the package (e.g., shaped like an arrow). These above indicators can sometimes be referred to as “orientation indicators.” Embodiments other than these are possible.

In some embodiments, the indicator is used to communicate a characteristic of the package having to do with its type as opposed to a physical location or orientation, which can be referred to “type indicators.” For example, two different types of packages can often look the same to a technician or mounting mechanism, and/or can have the same footprint. The inclusion of a first type of indicator on one type of package and either no indicator or a second type of indicator on another type of package can differentiate the package types. These characteristics include but are not limited to type of chip(s) within the package, number of chips within the package, epitaxial characteristics, emission color, emission brightness, etc. In one embodiment, a type indicator is located such that the optical element is still symmetrical despite the inclusion of the indicator, since the optical element can still communicate the type of package despite being symmetrical, which may not be possible in orientation indicators. This can sometimes increase emission uniformity. Many different type characteristics can be communicated by indicators according to the present invention, and the above examples are in no way limiting.

Combination indicators are also possible. For example, in any of the below embodiments and in other embodiments of the present invention, one characteristic of an indicator can communicate type while another characteristic of the indicator can communicate orientation, polarity, or some other characteristic. In one embodiment, the shape of the indicator communicates the type of package while the location of the indicator communicates orientation, polarity, etc. In other embodiments, two different indicators are used, one as an orientation indicator and one as a type indicator. Many different embodiments and combinations are possible.

The present invention is described herein with reference to certain embodiments, but it is understood that the invention can be embodied in many different forms and should not be construed as limited to the embodiments set forth herein. In particular, the present invention is described below in regards to certain LED packages having LED chips in different configurations, but it is understood that the present invention can be used for many other LED packages with other LED configurations. The LED packages can also have many different shapes beyond those described below, such as rectangular, and solder pads and attach pads can be arranged in many different ways. In other embodiments, the emission intensity of the different types of LED chips can be controlled to vary the overall LED package emission.

The present invention can be described herein with reference to conversion materials, wavelength conversion materials, remote phosphors, phosphors, phosphor layers and related terms. The use of these terms should not be construed as limiting. It is understood that the use of the term remote phosphors, phosphor or phosphor layers is meant to encompass and be equally applicable to all wavelength conversion materials.

The present invention can be described herein with reference to scatterers, scatters, scattering particles, diffusers, and related terms. The present invention can also be described herein with reference to reflectors, reflective particles, reflective surfaces, and related terms. The use of these terms should not be construed as limiting. It is understood that the use of these terms is meant to encompass and be equally applicable to all light scattering materials and/or reflective materials.

The embodiments below are described with reference to an LED or LEDs, but it is understood that this is meant to encompass LED chips, and these terms can be used interchangeably. These components can have different shapes and sizes beyond those shown, and one or different numbers of LEDs can be included. It is also understood that the embodiments described below utilize co-planar light sources, but it is understood that non co-planar light sources can also be used. It is also understood that an LED light source may be comprised of multiple LEDs that may have different emission wavelengths. As mentioned above, in some embodiments at least some of the LEDs can comprise blue emitting LEDs covered with a yellow phosphor along with red emitting LEDs, resulting in a white light emission from the LED package. In multiple LED packages, the LEDs can be serially interconnected or can be interconnected in different serial and parallel combinations.

It is also understood that when a feature or element such as a layer, region, encapsulant or submount may be referred to as being “on” another element, it can be directly on the other element or intervening elements may also be present. Furthermore, relative terms such as “inner”, “outer”, “upper”, “above”, “lower”, “beneath”, and “below”, and similar terms, may be used herein to describe a relationship of one layer or another region. It is understood that these terms are intended to encompass different orientations of the device in addition to the orientation depicted in the figures. Further, many of the embodiments of the present invention are shown with a “top” primary emission surface. It is understood that any one or more surfaces, including but not limited to a top surface, can be (or can combine to form) a primary emission surface. For example, a package can be designed to have a primary emission out a side emission surface.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the invention are described herein with reference to cross-sectional view illustrations that are schematic illustrations of embodiments of the invention. As such, the actual thickness of the layers can be different, and variations from the shapes of the illustrations as a result, for example, of manufacturing techniques and/or tolerances are expected. Embodiments of the invention should not be construed as limited to the particular shapes of the regions illustrated herein but are to include deviations in shapes that result, for example, from manufacturing. A region illustrated or described as square or rectangular will typically have rounded or curved features due to normal manufacturing tolerances. Thus, the regions illustrated in the figures are schematic in nature and their shapes are not intended to illustrate the precise shape of a region of a device and are not intended to limit the scope of the invention.

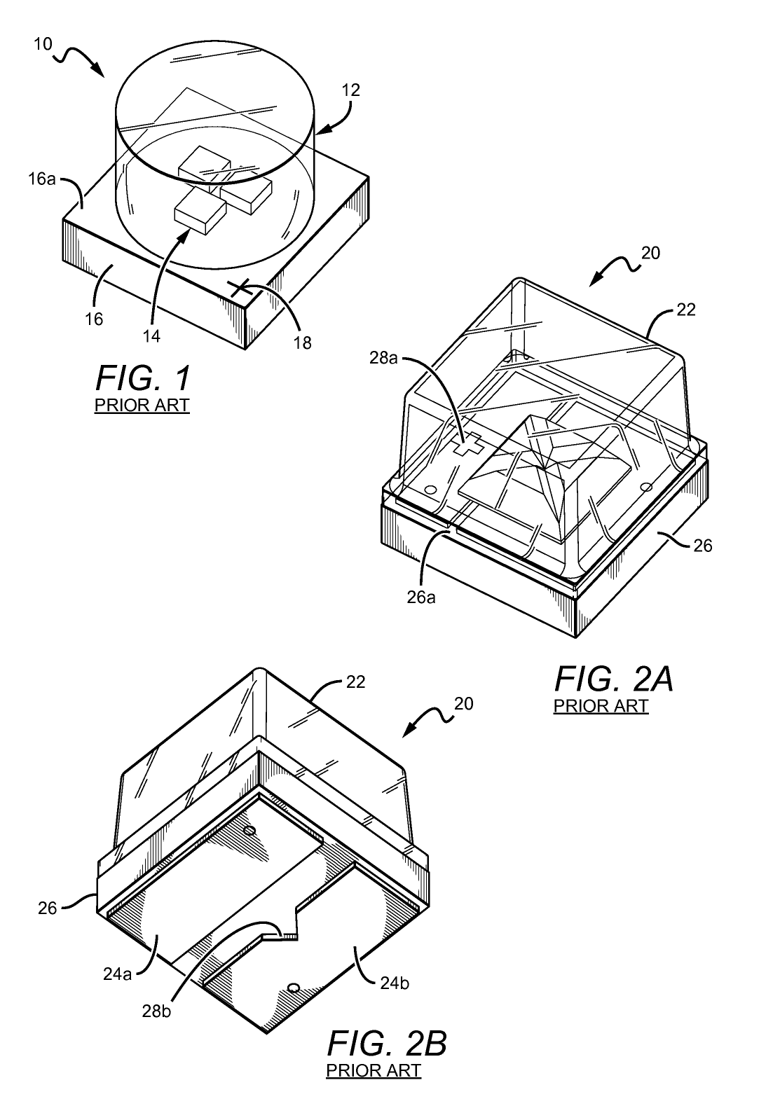

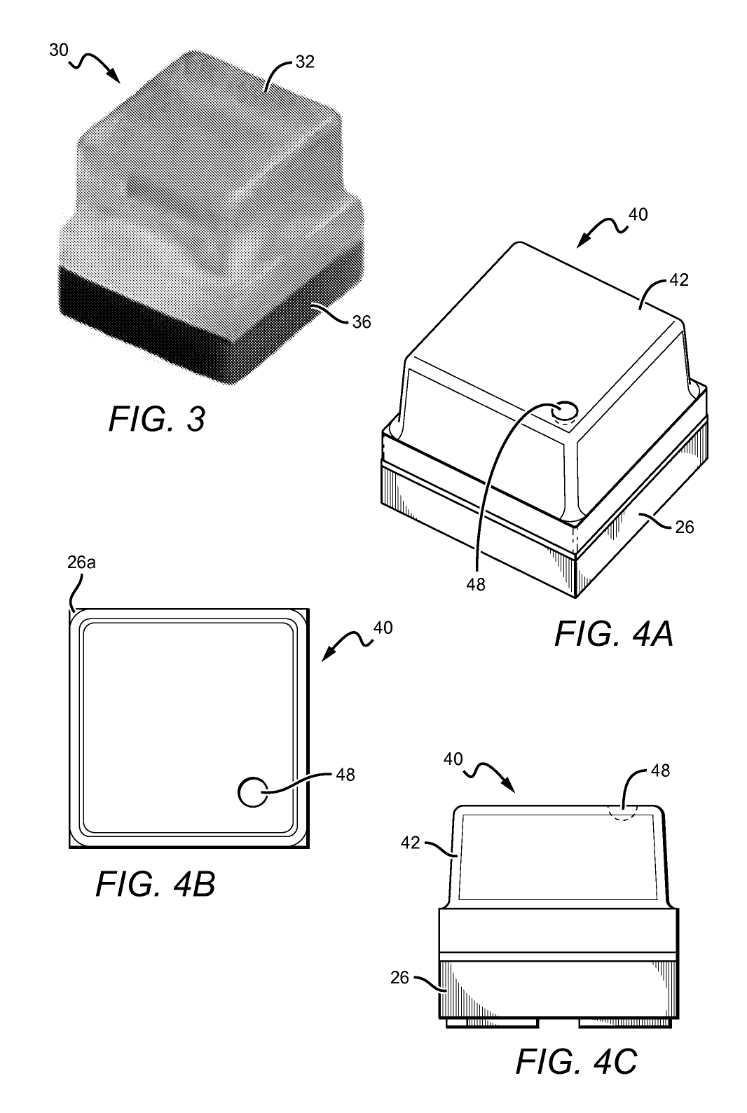

FIGS. 4A and 4B show an emitter package 40 comprising an encapsulant according to the present invention. The package 40 is similar in many ways to the package 20 from FIGS. 2A and 2B, and similar elements are marked with the same indicator numeral. However, as opposed to the clear encapsulant 22 of the package 20, the package 40 comprises an encapsulant 42 that is at least partially, and in some embodiments fully, opaque. This opaqueness can be due to many different factors, including but not limited to the material used for the encapsulant and/or additives within the encapsulant such as wavelength conversion elements or scattering particles, for example. One example of an opaque encapsulant is shown in FIG. 3, which comprises a silicone encapsulant with phosphor distributed therein.

Many different phosphors can be used in encapsulants according to the present invention being particularly adapted to lamps emitting white light. Light sources used in embodiments of the present invention can be LED based with at least some, and in some embodiments all, of the LEDs emitting light in the blue wavelength spectrum. The phosphor layer can absorb some of the blue light and re-emit yellow. This allows the lamp to emit a white light combination of blue and yellow light. In some embodiments, the blue LED light can be converted by a yellow conversion material using a commercially available YAG:Ce phosphor, although a full range of broad yellow spectral emission is possible using conversion particles made of phosphors based on the (Gd,Y)₃(Al,Ga)₅O₁₂:Ce system, such as the Y₃Al₅O₁₂:Ce (YAG). Other yellow phosphors that can be used for creating white light when used with a blue emitting LED based emitter include but are not limited to:
Tb₃₋ₓREₓO₁₂:Ce (TAG); RE=Y, Gd, La, Lu; or
Sr_{2-x-y}BaₓCa_{y}SiO₄:Eu.

Some arrangements according to the present invention can utilize multiple phosphors, such as two or more phosphors mixed in together or in separate sections. In some embodiments, each of the two phosphors can absorb the LED light and can re-emit different colors of light. In these embodiments, the colors from the two phosphor layers can be combined for higher CRI white of different white hue (warm white). This can include light from yellow phosphors above that can be combined with light from red phosphors. Different red phosphors can be used including:
SrₓCa₁₋ₓS:Eu, Y; Y=halide;
CaSiAlN₃:Eu; or
Sr_{2-y}Ca_{y}SiO₄:Eu

Other phosphors can be used to create color emission by converting substantially all light to a particular color. For example, the following phosphors can be used to generate green light:
SrGa₂S₄:Eu;
Sr_{2-y}Ba_{y}SiO₄:Eu; or
SrSi₂O₂N₂:Eu.

The following lists some additional suitable phosphors that can be used as conversion particles, although others can be used. Each exhibits excitation in the blue and/or UV emission spectrum, provides a desirable peak emission, has efficient light conversion, and has acceptable Stokes shift:

### Yellow/Green

(Sr, Ca, Ba) (Al, Ga)₂S₄:Eu²⁺

Ba₂(Mg, Zn) Si₂O₇:Eu²⁺

Gd_{0.46}Sr_{0.31}Al_{1.23}OₓF_{1.38}:Eu²⁺_{0.06}

(Ba_{1-x-y}SrₓCa_{y}) SiO₄:Eu

Ba₂SiO₄:Eu²⁺

Lu₃Al₅12 doped with Ce³⁺

(Ca, Sr, Ba) Si₂O₂N₂ doped with Eu²⁺

CaSc2O4:Ce³⁺

(Sr, Ba) 2SiO4:Eu²⁺

### Red

Lu₂O₃:Eu³⁺

(Sr₂₋ₓLaₓ) (Ce₁₋ₓEuₓ) O₄

Sr₂Ce₁₋ₓEuₓO₄

Sr₂₋ₓEuₓCeO₄

SrTiO₃:Pr³⁺, Ga³⁺

CaAlSiN₃:Eu²⁺

Sr₂Si₅N₈:Eu²⁺

Different sized phosphor particles can be used including but not limited to particles in the range of 10 nanometers (nm) to 30 micrometers (μm), or larger. Smaller particle sizes typically scatter and mix colors better than larger sized particles to provide a more uniform light. Larger particles are typically more efficient at converting light compared to smaller particles, but emit a less uniform light.

The converter can comprise one or multiple layers of different phosphor materials, with some multiple layer arrangements described in commonly assigned U.S. patent application Ser. No. 13/029,063 to Hussell et al. and entitled “High Efficiency LED Lamp With Remote Phosphor and Diffuser Configuration,” which is fully incorporated by reference herein in its entirety.

Different embodiments of packages according to the invention can also comprise different types and arrangements of scattering particles or scatterers. Some exemplary scattering particles include:
silica gel;
zinc oxide (ZnO);
yttrium oxide (Y₂O₃);
titanium dioxide (TiO₂);
barium sulfate (BaSO₄);
alumina (Al₂O₃);
fused silica (SiO₂);
fumed silica (SiO₂);
aluminum nitride;
glass beads;
zirconium dioxide (ZrO₂);
silicon carbide (SiC);
tantalum oxide (TaO₅);
silicon nitride (Si₃N₄);
niobium oxide (Nb₂O₅);
boron nitride (BN); and
phosphor particles (e.g., YAG:Ce, BOSE)

Other materials not listed may also be used. Various combinations of materials or combinations of different forms of the same material can also be used to achieve a particular scattering effect. For example, in one embodiment a first plurality of scattering particles includes alumina and a second plurality of scatting particles includes titanium dioxide. In other embodiments, more than two types of scattering particles are used. Scattering particles are discussed generally in the commonly assigned applications U.S. patent application Ser. No. 11/818,818 to Chakraborty et al. and entitled “Encapsulant with Scatterer to Tailor Spatial Emission Pattern and Color Uniformity in Light Emitting Diodes,” and U.S. patent application Ser. No. 11/895,573 to Chakraborty and entitled “Light Emitting Device Packages Using Light Scattering Particles of Different Size,” each of which is fully incorporated by reference herein in its entirety.

Embodiments of the present invention can include an indicator integrated into the encapsulant. These indicators can be, for example, orientation indicators, polarity indicators, type indicators, etc., which can indicate to a technician or machine any number of pieces of information about the package. It is understood that the terms “indicator,” “orientation indicator,” “polarity indicator,” “type indicator,” and other similar terms are used interchangeably herein unless otherwise noted, such as when specifically referring to an orientation, polarity, or package type, for example.

Indicators according to the present invention can communicate many different package characteristics. In one embodiment an indicator communicates the polarity of the package. In another embodiment the indicator communicates the mounting orientation of the package. In another embodiment the indicator communicates the location of one or more solder pads. In another embodiment the indicator communicates the primary emission direction of the package. In another embodiment the indicator communicates the number and/or type of chips within the package. In another embodiment the indicator communicates one or more emission characteristics of the package, such as emission color, brightness, and/or emission pattern. Any of the indicators described herein, including those described in relation to the below embodiments, can serve to communicate any type of information about the package which the user desires it to communicate. Further, any characteristic of the indicator, including but not limited to shape, size, location, additive/subtractive, and other characteristics can serve to communicate one or more pieces of information to the user.

Each characteristic can indicate a different piece of information, such that the number of pieces of information that can be communicated is limited only by the number of characteristics of the indicator. For example, location can indicate a first characteristic, location a second characteristic, size a third characteristic, etc. Further, one characteristic could communicate more than one piece of information. For example, location can indicate two or more characteristics, such as one orientation characteristic and one type characteristic. The presence of an indicator on the corner of an optical element may communicate an orientation and that the package is of a first type; the presence of an indicator displaced from the corner toward the center of the optical element may communicate an orientation and that the package is of a second type. Many different embodiments are possible.

Polarity indicators can be particularly useful in cases when a majority of a top surface of a substrate or submount is covered, such as by the encapsulant or optical element. In some embodiments of the present invention, 80% or more of the top surface is covered. In some embodiments 90% or more is covered. In some embodiments 95% or more is covered. In some embodiments, such as the package 40 from FIGS. 4A-4C, substantially all of the top surface of the substrate is covered.

The package 40 comprises an encapsulant 42 which itself comprises and/or is shaped to define and/or has a shape that comprises an indicator 48. The indicator 48 can be, for example, additive or subtractive. These terms are used interchangeably herein unless specifically noted otherwise. The encapsulant can be made of many different materials; one common material is silicone. The integrated indicator 48 can be concave and/or subtractive, and can be formed by creating a void within the encapsulant 42, although other embodiments are possible. In the embodiment shown the indicator 48 is a hemispheric or frustospheric void, although many different shapes are possible, some of which will be described below. In the embodiment shown the indicator 48 has a diameter of about 50 μm to about 1 mm, or about 100 μm to about 500 μm, or about 300 μm, although many different sizes are possible. In one embodiment the diameter is about 500 μm or less.

The indicator 48, and other indicators described herein, can indicate to a technician a particular corner or side of interest. For example, the indicator 48 in FIGS. 4A and 4B is in the lower-right corner; this could indicate that the right side is, for example, the cathode side. What the indicator indicates can be determined by the user. Further, while the indicator 48 is located in a corner, indicators can be placed anywhere where they distinguish a particular portion and/or side of the package. For example, if the indicator 48 were halfway up the right side of the encapsulant 42 in FIG. 4B instead of in the location shown, then the right side of the encapsulant would be visually distinguished for the technician to determine the proper placement and/or orientation of the package 40. In some embodiments of the present invention, such as some embodiments where indicators are used to indicate a certain side/corner/portion of the package and/or to indicate mounting orientation, indicators are included at points that are not the intersection of two lines of symmetry.

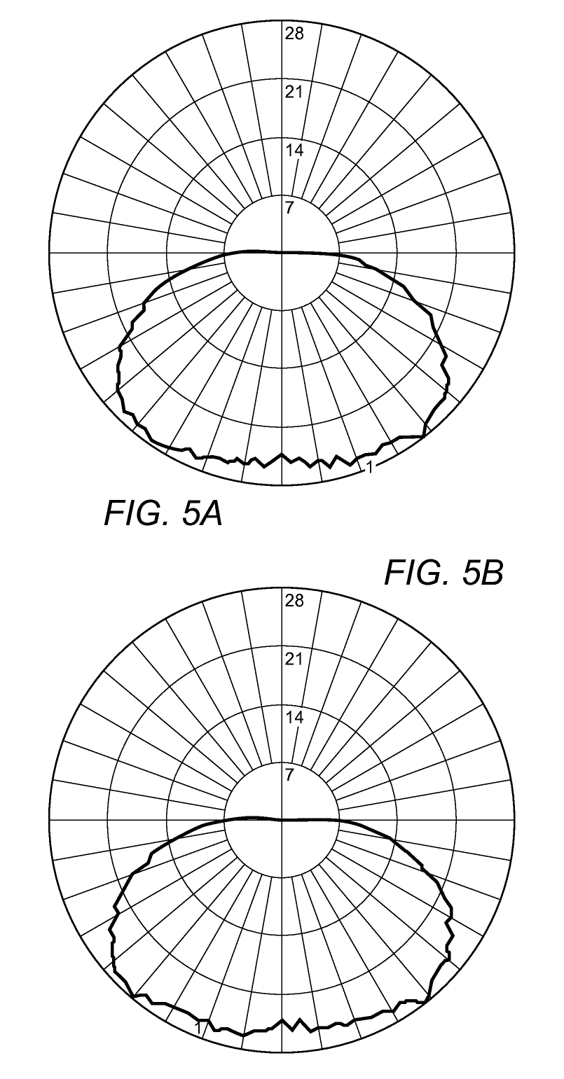

Integrated indicators according to the present invention, such as the indicator 48, can be big enough to be visible to the human eye, while minimizing any effect on the output profile of a package, such as the package 40. For example, FIG. 5A shows a distribution plot of a package similar to the package 20 from FIG. 2A, while FIG. 5B shows a distribution plot of a package similar to the package 40 from FIG. 4A, the only difference between the FIG. 5A and FIG. 5B package being the presence of an indicator similar to the indicator 48 and having a diameter of about 200 μm. As can be seen, the presence of the indicator can have very little effect on the output profile of the package. In one measured embodiment, the presence of the indicator increased beam spread by about 5.0° or less, or about 3.0° or less. In the specific embodiment shown, the beam spread of the package is increased from about 37.5° to about 40° (an increase of about 2.5°) due to the presence of the integrated indicator 48. Further, the presence of the indicator had little or no effect on the lumen output of the package; the FIG. 5A package emitted 113.51 m while the FIG. 5B package emitted 113.51 m.

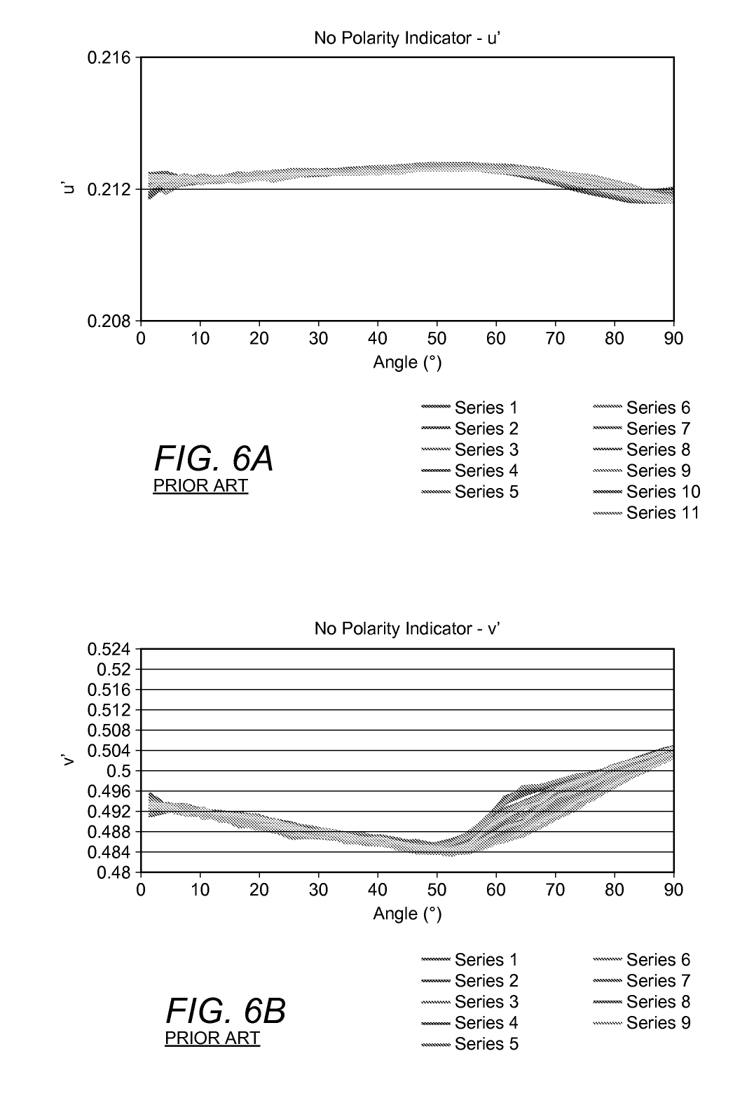

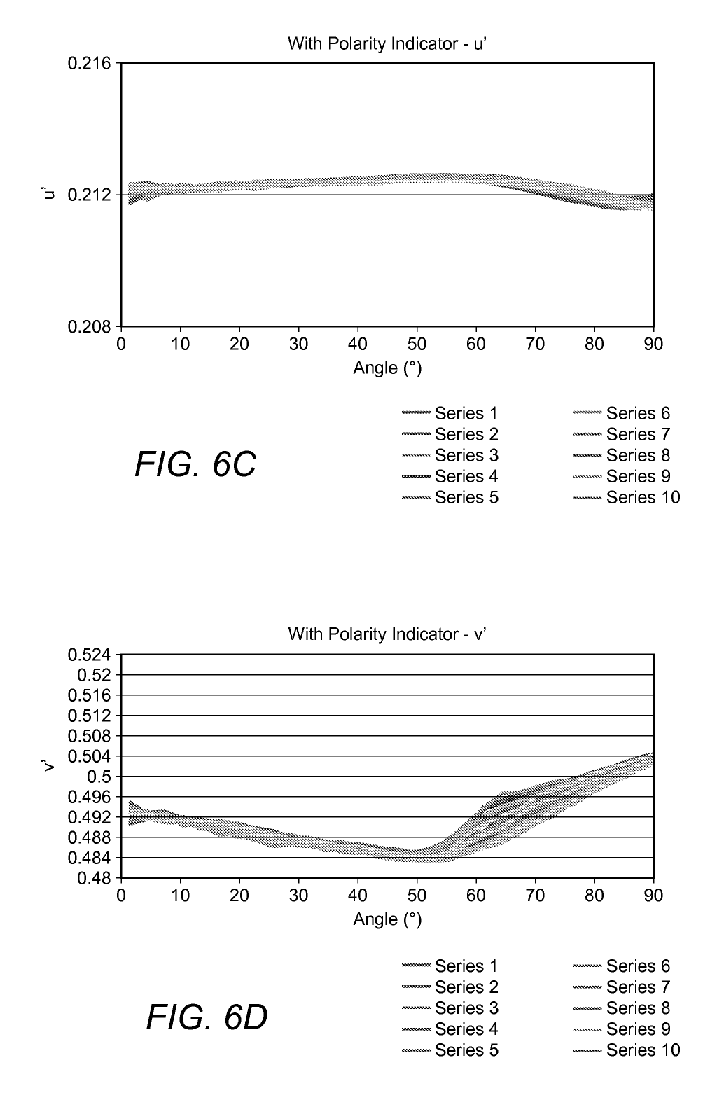

The color output along two axes of the FIG. 5A package and the FIG. 5B package were also measured. FIGS. 6A and 6B show the color output of the FIG. 5A package along u′ and v′ axes, and FIGS. 6C and 6D show the color output of the FIG. 5B package along the u′ and v′ axes. As can be seen by comparing the graphs, the presence of the indicator had minimal effect on the color output of the package.

While the encapsulant 42 is shown as generally rectangularly prismatic and with side walls that taper inward as they rise, it is understood that the encapsulant and other encapsulants described herein comprising indicators can take many different shapes, including hemispheric, frustospheric, cubic, rectangular prismatic, cylindrical, etc. Some encapsulant shapes are described, for example, in U.S. patent application Ser. No. 13/902,080 to Lowes et al. and entitled “Emitter Package with Integrated Mixing Chamber,” which is commonly assigned with the present application and which is fully incorporated by reference herein in its entirety. Polarity indicators according to the present invention can be used in conjunction with encapsulants of any shape.

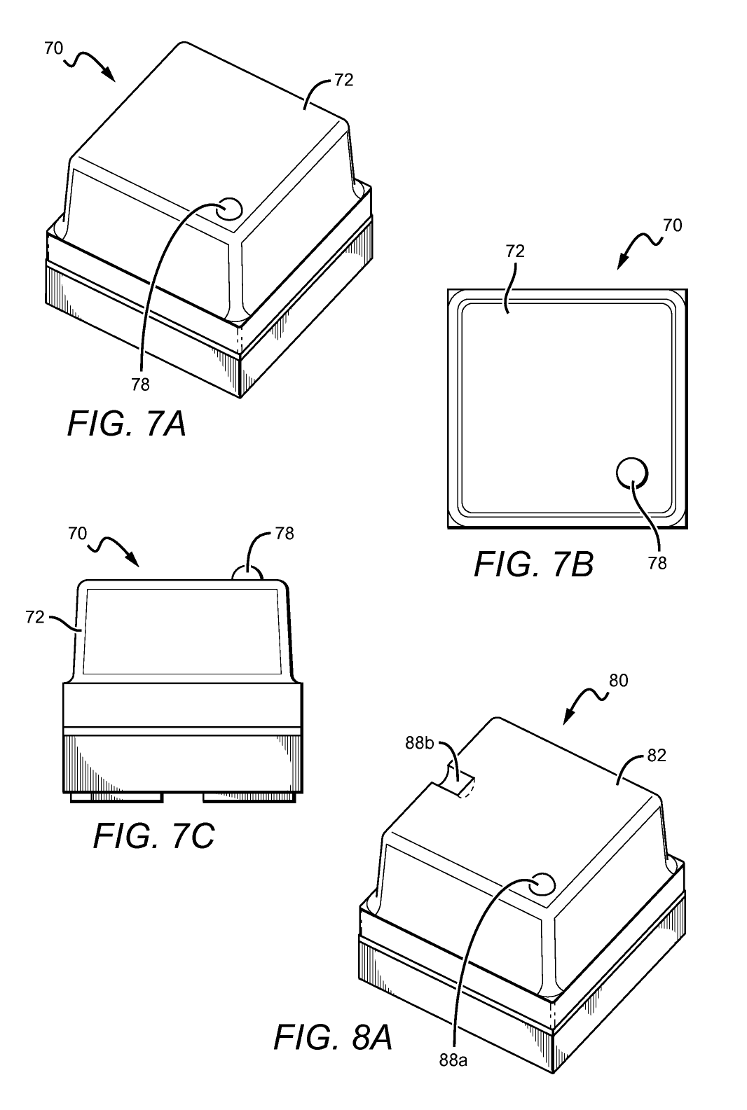

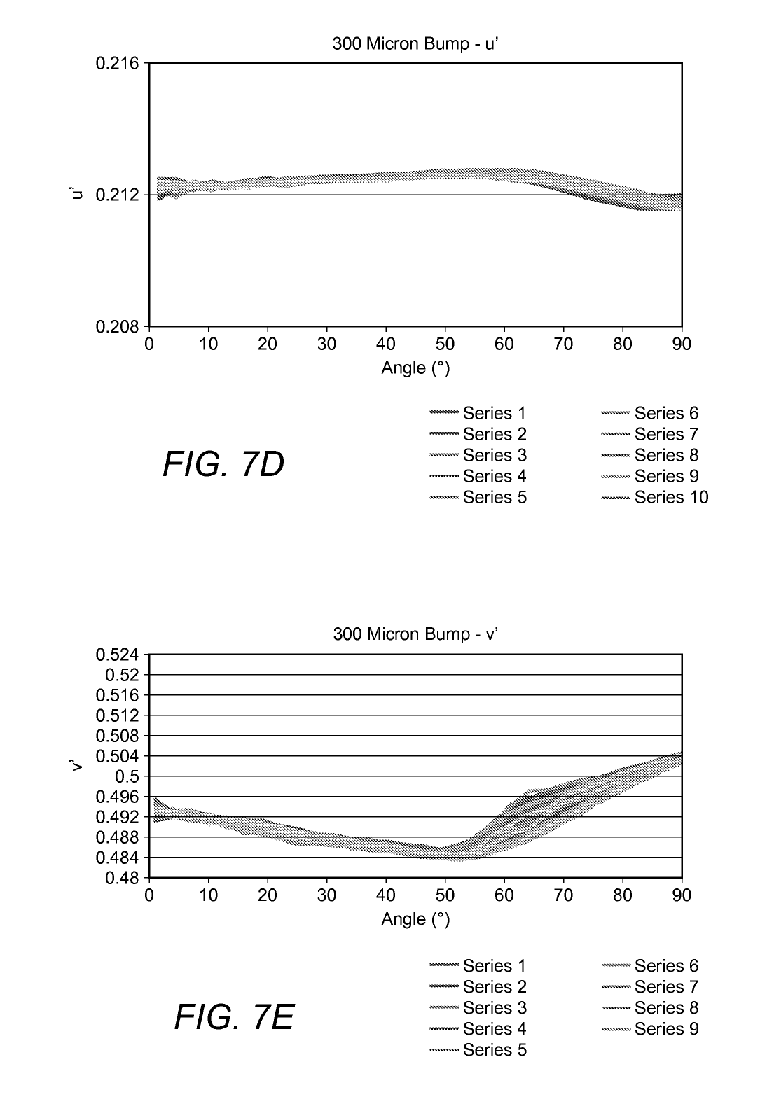

While the indicator 48 from FIGS. 4A and 4B is subtractive and concave, indicators according to the present invention can be additive and/or convex. For example, FIGS. 7A-7C show a package 70 similar to both the package 20 from FIGS. 2A and 2B and the package 40 from FIGS. 4A and 4B. The package 70 includes an indicator 78, which can be both additive, convex, or both. In the specific embodiment shown the indicator 78 is a hemisphere or frustosphere, although many different embodiments are possible. Additive and/or convex indicators can help to prevent buildup of unwanted contaminants, such as dirt, within an indicator, which may occur in some subtractive indicators and have an effect on output.

A device similar to the package 70 was measured as having an output very similar or identical to the outputs of the packages that are shown in FIGS. 5A-6D. The device emitted 113.51 m. The color output along u′ and v′ axes is shown in FIGS. 7D and 7E, and is very similar to that shown in FIGS. 6A-6D.

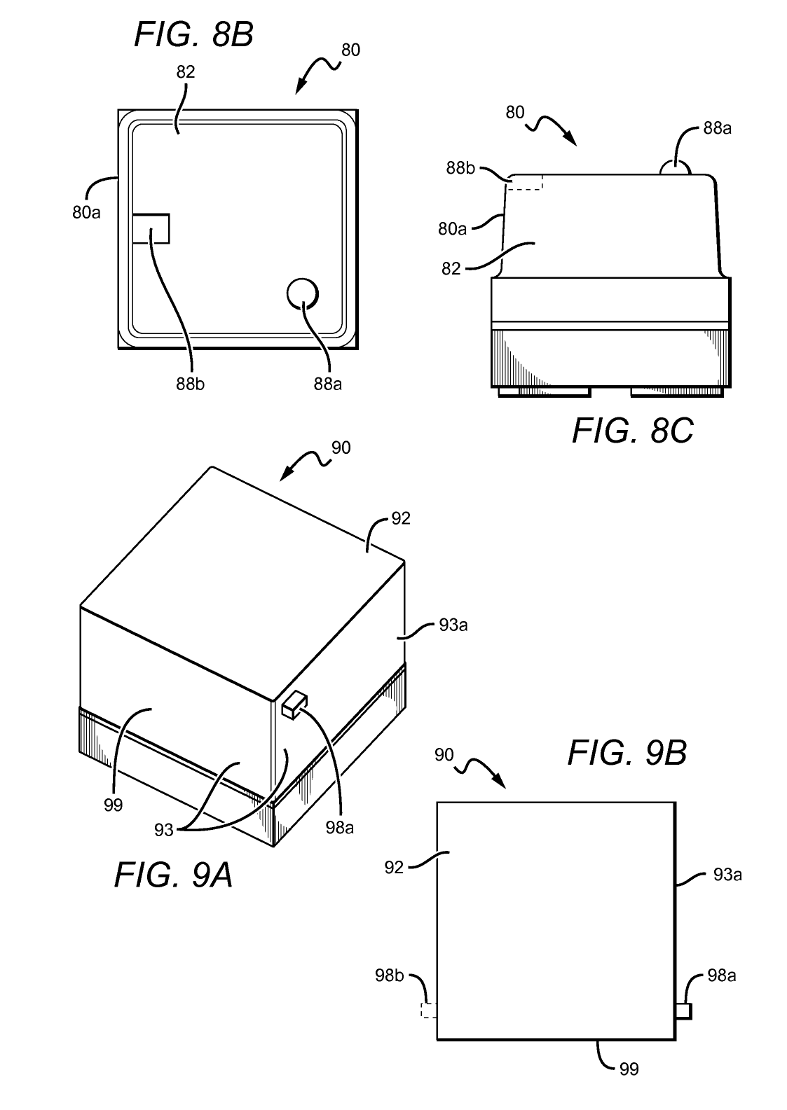

Embodiments of the present invention can include more than one indicator, and in some embodiments different indicators can indicate different package qualities. For example, FIGS. 8A-8C show a package 80 having two indicators 88a,88b. In one embodiment of the package, the indicators 88a,88b indicate different qualities; in one such embodiment, the indicator 88a indicates polarity, while the indicator 88b indicates primary emission direction. For example, the indicator 88b can indicate that the side 80a of the package corresponds to the package primary emission direction. In another embodiment, one of indicators 88a,88b is an orientation indicator, while the other of the indicators 88a,88b is a type indicator. Many different embodiments are possible.

While in the embodiment shown the indicator 88a is an additive frustosphere and the indicator 88b is a subtractive frustocylindrical trench, these indicators can take any shape and any placement that indicates a certain type of orientation and/or package characteristic. In some embodiments including that shown, different shapes are used to indicate different qualities. However, this need not always be the case. For instance, in some embodiments indicator location can be used with indicators of the same shape, such as a corner indicator with a position similar to the indicator 88a indicating a first quality, such as polarity, and a side indicator with a position similar to the indicator 88b indicating another quality, such as primary emission direction. Examples of different pieces of information that can be communicated have been described above, and as with all other indicators described herein, the piece(s) of information communicated by the indicators 88a,88b are in no way limited.

While the encapsulants 42 and 72 from FIGS. 4A and 4B, 7A-7C, and 8A-8C, respectively, are shown as at least partially opaque, the use of integrated indicators is not limited in this way. Integrated indicators can be used in clear, transparent, and/or translucent encapsulants as well. Manufacturing an integrated indicator according to the present invention may be more efficient than using a different type of indicator, and thus integrated indicators can be used even when not necessary, such as in packages with a clear encapsulant where an indicator could otherwise be placed on an element on the top surface of the substrate (see, e.g., the package 20 and indicator 28a from FIG. 2A).

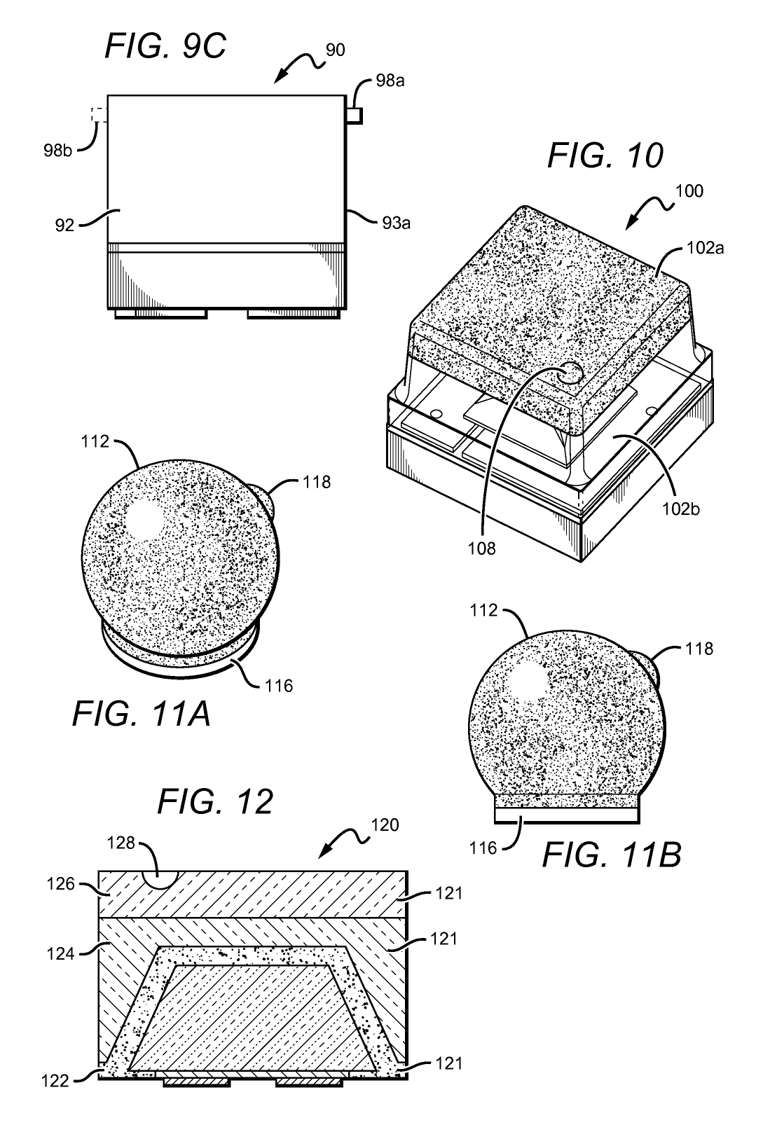

While the packages shown above include an indicator on a top surface, many different locations are possible. For example, the package 90 in FIGS. 9A-9C includes an encapsulant 92 with sidewalls 93, and an indicator 98a included on a sidewall 93a. The indicator 98a is also rectangularly prismatic, although many different shapes are possible, including but not limited to hemispheric, frustospheric, and square. Polarity indicators can be included on any side surface of encapsulants having one or more side surfaces.

In some instances, two indicators can be included on an encapsulant. This can in some instances facilitate easier fabrication. In these cases, the indicators can be mirror images of one another, such as the indicators 98a,98b best seen in FIGS. 9B and 9C (with the indicator 98b in broken line because it is not present in all embodiments). For packages comprising mirror image indicators such as the indicators 98a,98b, the indicators can be located such that half of the package is a mirror image of itself along one or fewer axes bisecting the package. Otherwise, the indicators may leave users with more than one possible placement orientation. For example, as best shown in FIG. 9B, the package 90 is a mirror image of itself over only one of the y-axis and x-axis (in this specific embodiment, the y-axis). Thus, the indicators 98a,98b can distinguish the indicated side 99 of the package 90. The side 99 could indicate, for example, the cathode side, the anode side, or the “top” side for placement, depending on user preference.

Many different methods can be used to fabricate the indicators 98a,98b. For instance, the indicators can be attached to the rest of the optical element 92 after it is already hardened, such as by a welding or molding process. Alternatively, the encapsulant 92 including the indicators 98a,98b can be molded at once, such as by injection molding. Many different methods are possible.

Encapsulants can have different sections of opaqueness and clearness. For example, particles used in embodiments of the present invention, including but not limited to wavelength conversion particles, phosphor particles, scattering particles, and quantum dots, can be distributed in different regions with different types of particles and/or different concentrations of particles. Encapsulants having different particle regions are described in U.S. patent application Ser. No. 12/498,253 to Le Toquin and entitled “LED Packages with Scattering Particle Regions,” and U.S. patent application Ser. No. 13/902,080 to Lowes et al. and entitled “Emitter Package with Integrated Mixing Chamber,” each of which is commonly assigned with the present application and each of which is fully incorporated by reference herein in its entirety.

While an indicator on the top surface of the substrate may be visible when the package is viewed from a certain angle in some embodiments, viewing such an indicator could prove to be difficult and require excessive time and/or effort, unlike an integrated indicator. Thus, the use of an integrated indicator can improve mounting ease and efficiency. For example, FIG. 10 shows an example of a package having such an encapsulant. The encapsulant 102 can include a first section 102a that is at least partially opaque and a second section 102b that is substantially clear. In this specific embodiment, the top portion of the encapsulant 102 is opaque while the bottom is clear, meaning that a technician might could see an indicator on the substrate if viewed at a very flat angle. However, the encapsulant 102 can include an integrated indicator 108, which can be the same as or similar to the indicators described above, in order to make indicator identification easier.

While the above embodiments describe indicators integrated into encapsulants, it is understood that indicators according to the present invention can be included in many different types of elements and optical elements, including but not limited to remote phosphor elements. For instance, indicators can be included in embodiments described in commonly assigned U.S. patent application Ser. No. 14/185,123 to Kircher et al. and entitled “Remote Phosphor Element Filled with Transparent Material and Method for Forming Multisection Optical Elements,” which is fully incorporated by reference herein in its entirety. Some embodiments described in this patent comprise an optical element mounted to a substrate/source arrangement or an LED package. In some of these embodiments, the optical element may block or cover areas where prior art indicators would be included, such as the top surface of the substrate. Optical elements including an integrated indicator may be particularly suited for such cases.

FIGS. 11A-11C show an optical element 112 mounted on a substrate 116. The optical element 112 is in this case opaque, although in other embodiments it may be clear. The optical element 112 can, as shown, cover most of the top surface of the substrate 116, leaving little or no room for placement of an indicator. The optical element 112 can include an indicator 118. In the specific case shown, the indicator 118 is an additive frustosphere or “bump”; however, many different embodiments, including but not limited to those previously described, are possible. The indicator 118 can indicate the orientation in which the optical element 112/substrate 116 combination is to be mounted, such as in a fixture like a bulb or bay light.

Polarity indicators can also be particularly applicable to emitters that are not on a traditional substrate and/or emitters with a hard or rigid optical element. For example, commonly assigned U.S. patent application Ser. No. 14/053,404 to Heikman et al. and entitled “Chip with Integrated Phosphor,” which is fully incorporated by reference herein in its entirety, describes “virtual wafers” of light emitters held together by converter material and/or one or more other layers. For example, FIG. 12 shows an emitter package 120 that can be part of such a virtual wafer prior to singulation. The package 120 can include one or more holding layers 121. In a wafer of packages similar to 120, the holding layers can form one or more common layers, or layers which interconnect two or more packages. In this specific embodiment, the holding layers 121 comprise a converter layer 122, and can comprise one or more utility layers such as the utility layers 124, 126. The converter layer 122 can comprise wavelength conversion material, while the utility layers 124, 126 can be substantially transparent, translucent, and/or clear, although many different layer combinations are possible. The holding layer or layers 121 can connect a plurality of packages to form a virtual wafer.

Whether part of a wafer comprising packages 120 or part of a singular package 120, one or more of the holding layers 121 can provide the primary mechanical support for the package. In this sense, these one or more holding layers 121 can provide the support that would otherwise be provided by a traditional substrate.

In one embodiment the bottom utility layer 124 can be silicone while the top utility layer 126 can be glass, plastic, or silicone. In other embodiments only one layer may be present, such as a layer of glass, silicone, or another material. The use of a material that is more hard and/or rigid than a silicone bottom utility layer 124, such as glasses like borosilicate glass or plastic, can increase the stability of the virtual wafer and/or can decrease or eliminate mechanical distortion due to shrinking of the bottom utility layer during cooling, such as that which may occur after high temperature curing. This process is described more fully in U.S. patent application Ser. No. 14/053,404 to Heikman et al.

In one embodiment, packages such as the package 120 can have a top layer that is shaped to define an integrated indicator, such as the integrated indicator 128. It is understood that while the top layer can be shaped to define an integrated indicator, other layers may also be shaped to define the same indicator. For example, a subtractive indicator may extend beyond the top layer into one or more of the layers below.

While the integrated indicator 128 is substractive, it can be additive in other embodiments, and can have any of the shapes or attributes of integrated indicators previously described. Polarity indicators in packages similar to the package 120 can be formed on a top surface prior to singulation. Alternatively, they can be formed on a side surface of the package, such as after singulation.

Optical elements according to the present invention can be manufactured in many different manners, such as by molding (including overmolding). If being manufactured by molding, the mold cavity can be altered to include an indicator portion. In one specific additive method, an indicator feature can be molded or welded onto the remainder of the encapsulant. Welding or molding can occur during or after the hardening or curing of the encapsulating material, for example. U.S. patent application Ser. No. 14/185,123 to Kircher et al. describes methods of forming multisection optical elements which can be applied to the present invention; for example, the indicator of the present invention can be attached to the remainder of the encapsulant just as different sections of an optical element are attached to one another in U.S. patent application Ser. No. 14/185,123. In another similar method, an optical element, such as a glass optical element, can be softened and reshaped to define an indicator, or can be softened and additional material welded onto or otherwise attached to the main glass element to form the indicator.

In one specific subtractive method, an indicator imprint can be pushed into an optical element to form a subtractive indicator such as the indicator 48 from FIGS. 4A-4C. Depending on, for example, the hardness of the encapsulant material, this imprinting can occur when the encapsulant is partially cured and/or hardened, or can occur after curing and/or hardening. Alternatively the imprint can be placed in the optical element material prior to curing/hardening, and remain in place during part or all of the curing/hardening process. One such example is injection molding in a mold including an imprint.

Another specific subtractive method is bead blasting or sand blasting. A specific target area of an optical element can be isolated, such as by a metal mask, and blasted with high velocity beads and/or sand to form a subtractive indicator. This method can be used with softer optical elements, such as silicone, but is particularly well adapted for use with harder materials such as glass.

Another method of forming indicators according to the present invention can include imprinting and/or ablation, such as by laser. Although laser methods can be used to form an indicator on any type of optical element, these methods can be particularly applicable to subtractive indicators, optical elements which are not molded, and/or optical elements which comprise a hard material, such as certain glasses including borosilicate glass. For example, this method can be used with packages similar to or the same as the package 120 from FIG. 12.

One device that can be used to form indicators according to the present invention is the Universal® Laser Systems VLS Desktop Series, such as the VLS 2.30 or VLS 3.50, the data sheets of which are fully incorporated by reference herein in their entirety. Many other systems can also be used. The intensity of the laser used can depend on a number of factors, including but not limited to the properties of the host material (e.g., hardness, optical properties, thickness, etc.) and the desired properties of the indicator (e.g. depth, width, shape, etc.).

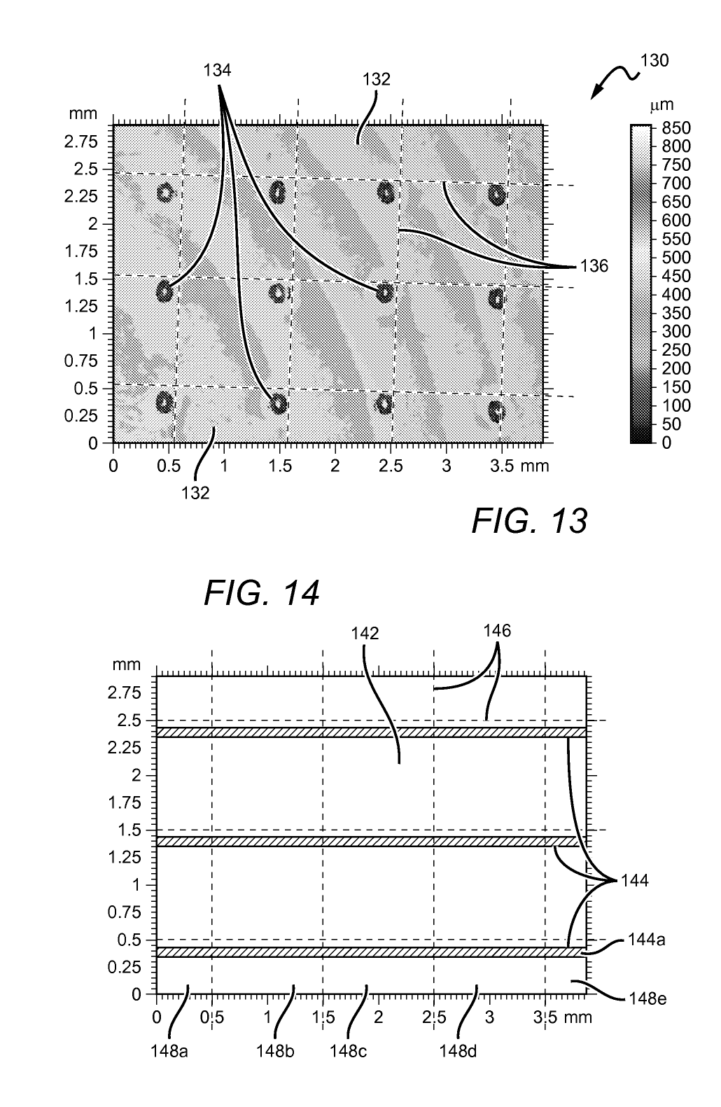

FIG. 13 shows non-contact surface profilometer readings from a piece of borosilicate glass 130 in which voids or holes have been placed using laser ablation, although it is noted that FIG. 13 can be representative of any type of surface made of any material. The borosilicate glass is representative of a top layer of one or more common layers interconnecting emitter packages, such as the top utility layer 126 of a virtual wafer comprising a plurality of devices 120 from FIG. 12. The emitter packages represented by FIG. 13 are approximately 1 mm×1 mm square, and may have very little or no visible substrate top surface for placement of an indicator. The voids or holes are representative of integrated indicators in a top surface of these packages which are, in this case, subtractive. Areas 132 of the profilometer readings correspond to the top surface of the top layer (in this case, glass), while the circular segments 134 correspond to holes or voids. Lines 136 substantially correspond to singulation lines along which packages can be divided, leaving indicators in the upper-right corner of each package.

As can be seen using the scale, the top surface corresponds to a reference height of approximately 500-600 μm, or about 550 μm. The bottoms of the holes correspond to a reference height of about 50-150 μm, or about 100 μm. Thus, in this case, the integrated indicators have a depth of about 350-550 μm, or about 450 μm. Many different depths are possible, as previously described. For example, in the previously described frustospherical subtractive indicator 48 from FIGS. 2A-2C, if the indicator 48 is hemispheric and has a diameter of about 300 μm then the depth will be approximately 150 μm. The laser can be tuned based on the host material to form an indicator of whatever dimensions and/or depth are desired.

In the FIG. 13 embodiment the indicators are substantially cylindrical, as can be inferred from the fact that the transition from circular segments 134 to areas 132 is abrupt as opposed to graded. In other embodiments this transition can be more gradual, such as with a frustospherical indicator.

It should be noted that the streaks through areas 132 and the small circles in the middle of segments 134 represent interference and/or areas of no data, and as such are not indicative of any structure.

FIG. 13 shows discrete indicators represented by circular segments 134. These indicators can be formed, for example, by pulsing a laser as a plurality of packages is moved relative to the laser, or by moving the laser between pulses. Alternatively, in another embodiment continuous indicators (as opposed to discrete indicators) can be formed. For example, FIG. 14 shows a top surface 142 of a common layer. The planned singulation lines 146 can approximate the divide between packages. Continuous integrated indicators 144 can be included on the top surface 142, although other surfaces are possible. Continuous integrated indicators according to the invention, such as the indicators 144, can run between two or more packages and/or optical elements. For example, the continuous integrated indicator 144a runs between packages 148a, 148b, 148c, 148d, 148e (and runs between their respective optical elements, as well as their respective top layers). The indicators 144 can be formed using any of the previously described methods, including laser imprinting/ablation. If laser imprinting and/or ablation is used, the laser does not need to be pulsed, as it may need to be to form discrete indicators. The indicators 144 can be subtractive “trenches” that run between optical elements (or, in a package embodiment, a trench running across the optical element).

Continuous integrated indicators, such as the indicators 144, can be formed on packages so as to indicate one side or corner of the package. For example, in a square package such as those represented in FIG. 14, indicators can be formed such that they are symmetrical about only one of the x-axis and y-axis (e.g., in FIG. 14, the indicators are symmetrical about the y-axis of the packages but not the x-axis). Continuous indicators can be formed such that they are not along a line of symmetry of the host packages (e.g. the x-axis, y-axis, or a corner-to-corner axis), since placing an indicator along a line of symmetry can result in two possible orientations that will look equivalent to a technician during installation. Similarly, discrete indicators can be formed such that they are not at an intersection of two lines of symmetry. While FIG. 14 and the discussion thereof have focused on the formation of continuous integrated indicators at the wafer level, these indicators can also be formed at the package level, such as on any of the packages and/or optical elements described herein.

In the embodiments of the present invention, such as those described above, the integrated indicator can be designed to be visible to the human eye such that it can indicate to a technician the proper alignment of the package. In some embodiments, regardless of whether or not the integrated indicator is visible to the human eye but especially in embodiments where it is not, it may be more efficient to locate the indicator via machine and/or software, such as software with feature identification tools.

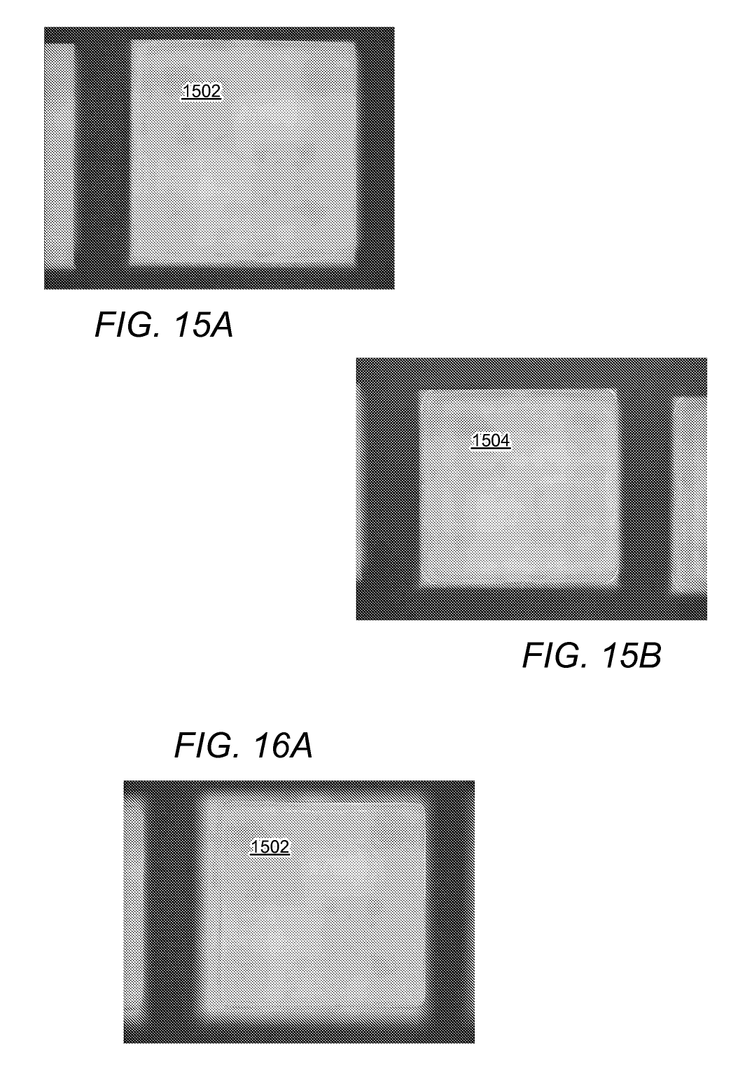

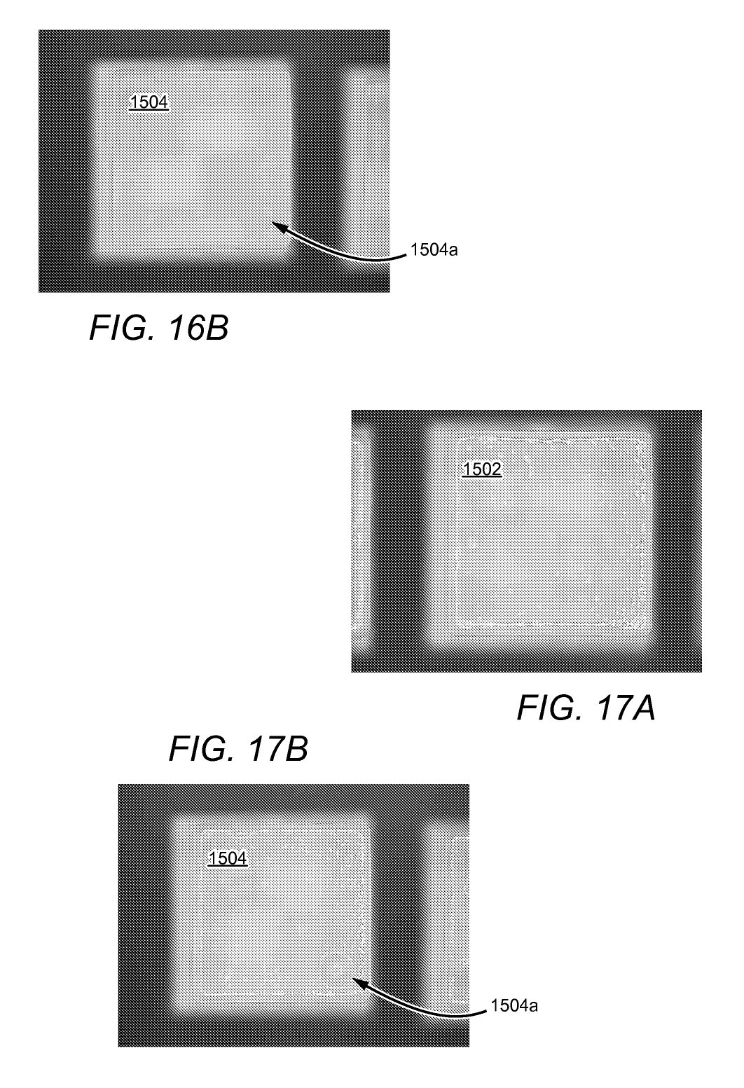

The placement of the indicator where it is visible from above (e.g., on a top or side surface of an optical element) can make the identification process easier and more efficient, since otherwise each package would have to be placed over a camera for feature identification, then physically moved to a mounting position. In order to best identify an indicator on the top surface of an optical element according to the present invention, the lens or identification tool should focus upon the elevation of the sought indicator (e.g., the top of the optical element). For instance, FIGS. 15A and 15B show fluorescent white light illumination of a package 1502 without an indicator and a package 1504 according to the present invention. The package 1504 is similar to the package 40 from FIGS. 4A and 4B, comprising an indicator in the lower right corner of the package as it is oriented in the figure. The identification tool in FIGS. 15A and 15B focused on the chips within the package. It is very difficult, if not impossible, to locate an indicator. FIGS. 16A-17B show the same packages 1502, 1504 with the focus on the top of the optical element, with both flat field illumination (FIGS. 16A and 16B) and reflective field illumination (FIG. 17A and 17B). The indicator 1504a can be seen in both FIGS. 16B and 17B. Both flat field illumination and reflective field illumination focused on the elevation of the indicator can identify the indicator, with reflective field illumination being particularly suited to indicator identification.

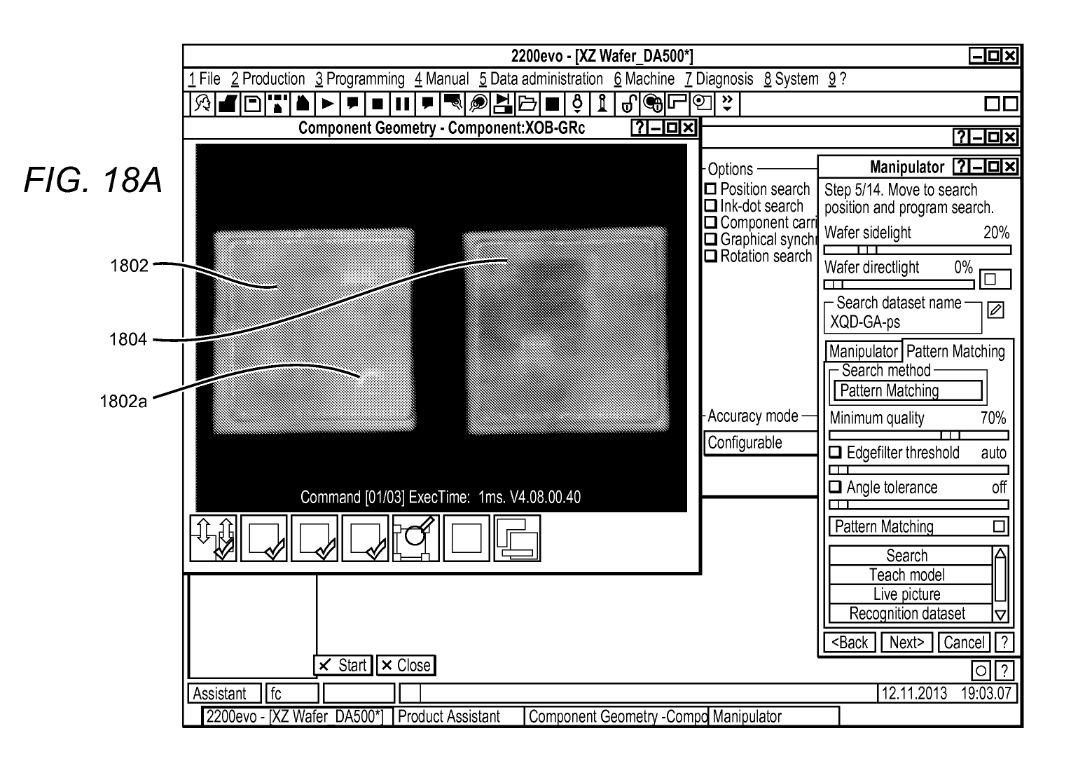

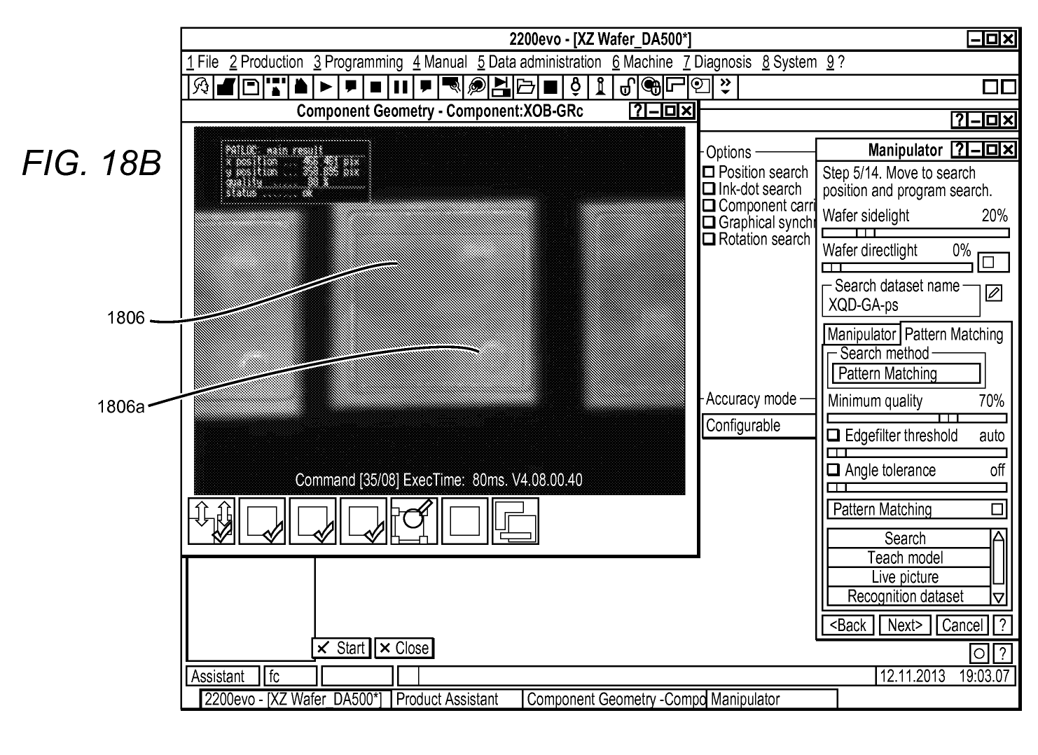

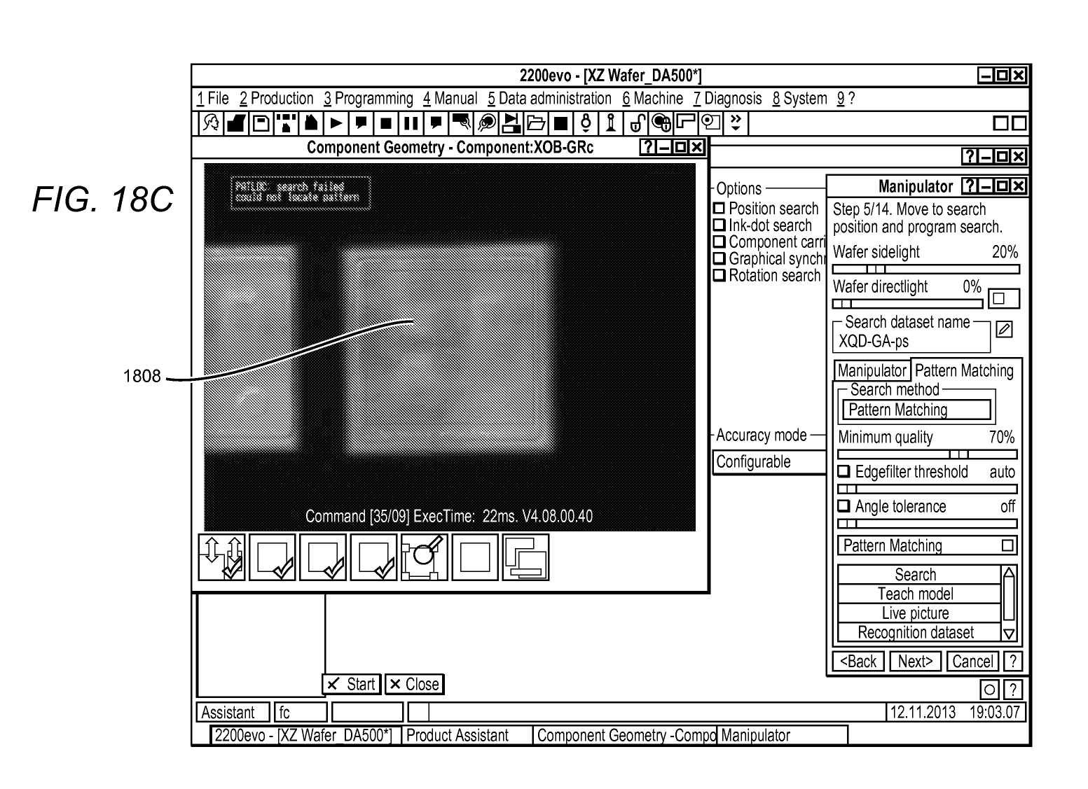

Software can be used in combination with pick-and-place mechanical devices in order to properly orient embodiments of the present invention. For example, FIGS. 18A-18C show screenshots of the pick-and-place tool of the Multichip Die Bonder 2200 evo, from Datacon, the data sheet of which is fully incorporated by reference herein. It is understood that many different types of software and mechanical devices, in combination or alone, can be used with embodiments of the present invention.

The setup in FIG. 18A can provide a control, wherein one image of a device 1802 with the feature in question (in this case, indicator 1802a) and one image of a device 1804 without an indicator are compared to one another by the program. This allows the program to identify the feature for which it is searching. The program can then determine a yield match threshold for each device it examines. FIG. 18B shows that when a package 1806 having an indicator 1806a is examined, the program shows a yield match threshold of 88%. FIG. 18C shows that when a package 1808 without an indicator is examined, the program shows a yield match threshold of 0%. In testing, a base yield match threshold of 70% resulted in 100% identification of packages including an indicator, meaning that every package including an indicator had a yield match threshold of at least 70% and no packages without an indicator had a yield match threshold of 70% or higher. In actual testing, no packages without indicators had a yield match threshold above 0%. It is understood that in other testing results may differ.

It is understood that embodiments presented herein are meant to be exemplary. Embodiments of the present invention can comprise any combination of compatible features shown in the various figures, and these embodiments should not be limited to those expressly illustrated and discussed.

Although the present invention has been described in detail with reference to certain preferred configurations thereof, other versions are possible. Therefore, the spirit and scope of the invention should not be limited to the versions described above.

1. A light emitting device, comprising:
an optical element comprising an indicator.

2. The light emitting device of claim 1, further comprising a substrate;
wherein said optical element is on 90% or more of a top surface of said substrate.

3. The light emitting device of claim 1, further comprising a substrate;
wherein said encapsulant is on substantially all of a top surface of said substrate.

4. The light emitting device of claim 1, wherein said optical element is substantially opaque.

5. The light emitting device of claim 1, wherein said optical element is substantially symmetrical but for said indicator.

6. The light emitting device of claim 1, wherein said package is substantially symmetrical but for said indicator.

7. The light emitting device of claim 1, wherein said package is configured to emit a lumen output substantially equal to an equivalent package without said indicator.

8. The light emitting device of claim 1, wherein said package is configured to emit light with an output profile substantially similar to an equivalent package without said indicator.

9. The light emitting device of claim 1, wherein said optical element is molded.

10. The light emitting device of claim 1, wherein said optical element comprises silicone.

11. The light emitting device of claim 1, wherein said optical element is an encapsulant.

12. The light emitting device of claim 1, wherein said optical element is a lens.

13. The light emitting device of claim 1, wherein the shape of said optical element comprises said indicator.

14. The light emitting device of claim 1, wherein said indicator indicates the proper mounting orientation for said light emitting device.

15. The light emitting device of claim 1, further comprising at least one electrical connection;
wherein said indicator indicates the polarity of said electrical connection.

16. The light emitting device of claim 1, wherein said optical element comprises a material more rigid than silicone.

17. The light emitting device of claim 1, wherein said optical element comprises glass.

18. The light emitting device of claim 1, wherein said optical element is the primary mechanical support for said device.

19. An optical element shaped to define at least one integrated indicator.

20. The optical element of claim 19, wherein said optical element is substantially symmetrical but for said at least one integrated indicator.

21. The optical element of claim 19, wherein said at least one integrated indicator is visible to the human eye.

22. The optical element of claim 19, wherein said integrated indicator comprises a first dimension of about 200 μm to about 500 μm.

23. The optical element of claim 19, wherein said optical element comprises said at least one integrated indicator.

24. The optical element of claim 19, wherein said at least one integrated indicator is additive.

25. The optical element of claim 19, wherein said at least one integrated indicator is subtractive.

26. The optical element of claim 19, wherein said at least one integrated indicator is frustospherical.

27. The optical element of claim 19, wherein said optical element is shaped to define at least one continuous integrated indicator that is not along a line of symmetry of said optical element.

28. A method of forming an optical element, comprising:
providing a substantially symmetrical optical element; and
forming an indicator such that said optical element is no longer substantially symmetrical.

29. The method of claim 28, comprising providing an emitter wafer, said emitter wafer comprising a plurality of packages each comprising an optical element; and
forming an indicator in each of said optical elements.

30. The method of claim 29, further comprising singulating said packages such that each package comprises only one indicator.

31. The method of claim 29, wherein said optical elements share a common layer divisible to form at least part of each of said optical elements; and
wherein said common layer is shaped to define said indicators.

32. The method of claim 31, wherein said indicators comprise discrete indicators formed in each of said optical elements.

33. The method of claim 31, comprising forming a continuous indicator, said continuous indicator comprising an indicator in two or more of said optical elements.

34. The method of claim 31, wherein said wafer is a virtual wafer.

35. The method of claim 31, wherein said common layer comprises a material more rigid than silicone.

36. The method of claim 31, wherein said common layer comprises glass.

37. The method of claim 28, wherein said indicator is formed by laser imprinting or ablation.

38. The method of claim 28, wherein said indicator is formed by molding.

39. The method of claim 28, comprising curing or hardening said optical element around an indicator imprint.

40. An emitter wafer, comprising:
a plurality of emitter packages, said emitter packages collectively comprising one or more common layers;
wherein said one or more common layers comprises a top layer; and
wherein said top layer is shaped to define an indicator in each of said emitter packages.

41. The emitter wafer of claim 40, wherein said indicator is continuous between two or more of said emitter packages.

42. The emitter wafer of claim 40, wherein said one or more common layers comprises a lower layer; and
wherein said top layer is more rigid than said lower layer.
